(19) United States
(12) Patent Application Publication
(10) Pub. No.: US 2007/0217272 A1
(43) Pub. Date: Sep. 20, 2007

(54) MEMORY DEVICE AND RELATIVE CONTROL METHOD

(75) Inventors: Carmela Giovanna Albano, Gravina Di Catania (IT); Mounia El-Moutaouakil, Andalo Valtellino (IT); Massimo Terragni, Milano (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/677,411

(22) Filed: Feb. 21, 2007

(30) Foreign Application Priority Data
Feb. 22, 2006 (IT) VA2006A000011

(51) Int. Cl. G11C 5/14

(52) U.S. Cl. 365/189.09

(57) ABSTRACT

A single job memory device includes an array of memory cells, row and column decoders and first and second charge pump voltage regulators controlled by respective first and second control circuits that supply the row and column decoders at least during write operations of data in the array of memory cells. A third charge pump voltage generator, controlled by a third control circuit, supplies the row and column decoders during read operations of data from the array of memory cells. The memory device includes a switching circuit that, during the read operations, disconnects two of the control circuits from the respective charge pump voltage generators, transmits control signals generated by the other control circuit to the first and second charge pump voltage generators, and shorts among them the output nodes of the voltage generators on which the supply voltages of the row and column decoders are generated.

### FIELD OF THE INVENTION

The invention relates to memory devices, and more particularly, to a memory device with reduced silicon area occupation and related control methods.

### BACKGROUND OF THE INVENTION

A memory device generally includes several charge pump generators for generating boosted voltages. Boosted voltages are higher than the supply voltage externally applied to the device, and are required during certain phases of operation for supplying certain circuits of the memory device. Boosted voltages are generally applied to row and column decoders through which memory locations of the array of memory cells are accessed.

FIG. 1 schematically depicts the connections for supplying boosted voltages generated by charge pumps to the row and column decoders of a memory cell array. A fourth charge pump VPD, commonly used for keeping the drain of selected memory cells at a pre-established voltage, has not been depicted because it is irrelevant for describing the addressed technical problem.

When a signal READ/VERIFY assumes a null logic state and thus starts a write operation of data in the memory locations, configuration switches make the row and column decoders to be supplied at the voltages produced by the respective charge pump generators VXP and VY. In contrast, when the signal READ/VERIFY switches active, it starts a read operation of data from the memory locations and configures the switches such that both decoders are supplied at the read voltage produced by the charge pump VXR.

The voltages generated by the three distinct charge pumps VXP, VY and VXR are identical, but their current delivering capability is different but appropriate for the requirements for the different operations.

In single job memory devices, the charge pumps VXP and VY are turned off during read operations. In contrast, during operations for modifying stored data, the charge pump VXR remains active because it is used for biasing the well region (into which the array of memory cells is realized) when the voltage generated by the generator VXP drops below the voltage generated by the charge pump VXR.

The need to supply simultaneously at relatively high voltage different circuits that have different current absorption characteristics implies for obvious optimization of consumption the need to integrate a number of distinctly controlled charge pump generators in the memory device, with a corresponding silicon area occupation.

### SUMMARY OF THE INVENTION

In view of the foregoing background, an object of the invention is to provide a method for efficiently controlling a single job memory device having an innovative architecture requiring a reduced silicon area occupation.

This and other objects, features and advantages in accordance with the invention are provided by maintaining on the charge pumps that normally supply row and column decoders during stored data modification operations, and also during read operations.

More precisely, the memory device and a related control method according to which, during a read operation, the control circuits of two distinct charge pumps, preferably of the charge pumps VXP and VY, are disabled and the three charge pump generators VXP, VY and VXR are all controlled by the control circuit of the third charge pump. This is preferably the VXR charge pump. The output nodes of all three generators on which the respective boosted voltages are produced may be connected in common.

The single job memory device may comprise an array of memory cells, row and column decoders and first and second charge pump voltage regulators controlled by respective first and second control circuits that supply the row and column decoders at least during write operations of data in the array of memory cells. A third charge pump voltage generator, controlled by a third control circuit, may supply the row and column decoders during read operations of data from the array of memory cells.

The memory device may further include a circuit that, during the read operations, disconnects two of the control circuits from the respective charge pump voltage generators, transmits control signals generated by the other control circuit to the first and second charge pump voltage generators, and shorts among them the output nodes of the voltage generators on which the supply voltages of the row and column decoders are generated.

### BRIEF DESCRIPTION OF THE DRAWINGS

This invention will be described referring to the attached drawings, wherein:

FIG. 1 is a block diagram of charge pump generators and row and column decoders of a memory device in accordance with the prior art; and

FIG. 2 is a block diagram of charge pump generators according to a preferred embodiment of the memory device in accordance with the invention.

### DETAILED DESCRIPTION OF THE PREFERRED EMBODIMENTS

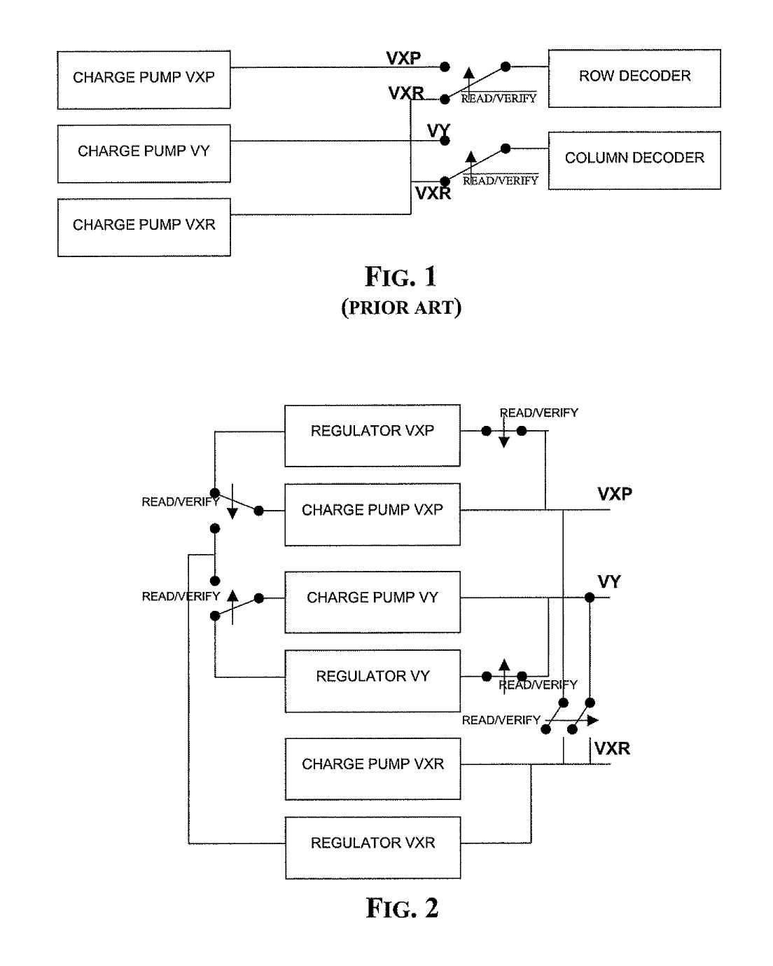

A preferred embodiment of the architecture of the single job memory device is depicted in FIG. 2. Beside the three charge pumps of FIG. 1, the respective control circuits REGULATOR_VXP, REGULATOR_VY and REGULATOR_VXR are also depicted. As in the prior art device of FIG. 1, the generators VY and VXP supply respectively the row and column decoders during data modification operations. The generator VXR biases the well region whenever the voltage VXP drops below the voltage VXR.

The main difference between the architecture depicted in FIG. 2 and the architecture depicted in FIG. 1 is, according to the control method of the invention, during read operations, all three charge pump generators are connected through a multiplexer or through configuration switches so that they are controlled by a single control circuit, and to the supply nodes of the row and column decoders. Thus, they all together contribute in delivering the current that is absorbed during read operations.

The control circuit used for controlling, during read operations, all three charge pump generators, may be any one of the existing control circuits REGULATOR_VXP, REGULATOR_VY and REGULATOR_VXR. Preferably, during read operations, the three charge pump generators are controlled by REGULATOR_VXR because typically it is the more precise and the fastest of the three control circuits of the charge pump generators. Moreover, the regulated voltage during read operations is generally different from the voltage that the charge pumps VY and VXP, driven by the respective control circuits, supply during data modification operations.

From FIG. 2 it is evident that during read operations the charge pumps VY and VXP are no longer controlled by their dedicated distinct control circuits but are controlled by the control circuit of the charge pump VXR. At the same time, through path selecting switches, the output nodes of the charge pumps VY and VXP are connected to the output node of the third charge pump VXR.

In other words, the stages of the charge pumps VXP and VY are electrically connected electrically in parallel among each other and in parallel with the stages of the third pump VXR. This both contributes in supplying the current absorbed both by the row decoder and by the column decoder during read operations. This allows formation of a VXR generator that occupies a significantly smaller silicon area than the device of FIG. 1, with an area saving substantially equivalent to the area occupied by the generators VXP and VY.

1-5. (canceled)

6. A memory device comprising:
an array of memory cells;
a row decoder coupled to said array of memory cells;
a column decoder coupled to said array of memory cells;
first and second control circuits;
first and second charge pump voltage regulators controlled by said respective first and second control circuits that respectively supply said row and column decoders at least during write operations of data in said array of memory cells;
a third control circuit;
a third charge pump voltage generator controlled by said third control circuit and supplying said row and column decoders during read operations of data from said array of memory cells; and
a switching circuit that operates as follows during the read operations
disconnecting two of said control circuits from their respective charge pump voltage generators,
transmitting control signals generated by said control circuit not disconnected to said first and second charge pump voltage generators, and
shorting together output nodes of said first, second and third charge pump voltage generators on which supply voltages for said row and column decoders are generated.

7. The memory device of claim 6, wherein said switching circuit disconnects said first and second control circuits during the read operations.

8. The memory device of claim 6, wherein said switching circuit comprises configuration switches controlled by a same signal for beginning the read operations.

9. The memory device of claim 6, wherein the two control circuits being disconnected are said first and second control circuits; and wherein said control circuit transmitting is said third control circuit.

10. A memory device comprising:
an array of memory cells;
a row decoder coupled to said array of memory cells;
a column decoder coupled to said array of memory cells;
first and second control circuits;
first and second charge pump voltage regulators controlled by said respective first and second control circuits that respectively supply said row and column decoders at least during write operations of data in said array of memory cells;
a third control circuit;
a third charge pump voltage generator controlled by said third control circuit and supplying said row and column decoders during read operations of data from said array of memory cells; and
a switching circuit that operates as follows during the read operations
disconnecting said first and second control circuits from their respective first and second charge pump voltage generators,
transmitting control signals generated by said third control circuit to said first and second charge pump voltage generators, and
shorting together output nodes of said first, second and third charge pump voltage generators on which supply voltages of said row and column decoders are generated.

11. The memory device of claim 10, wherein said switching circuit disconnects said first and second control circuits during the read operations.

12. The memory device of claim 10, wherein said switching circuit comprises configuration switches controlled by a same signal for beginning the read operations.

13. A method of controlling a memory device comprising an array of memory cells, row and column decoders coupled to the array of memory cells, first and second charge pump voltage regulators controlled by respective first and second control circuits that supply the row and column decoders at least during write operations of data in the array of memory cells, a third charge pump voltage generator controlled by a third control circuit and supplying the row and column decoders during read operations of data from the array of memory cells, the method comprising:
executing the following steps during the read operations
disconnecting two of the control circuits from their respective charge pump voltage generators,
transmitting control signals generated by the control circuit not disconnected to the first and second charge pump voltage generators, and
shorting together output nodes of the first, second and third charge pump voltage generators on which supply voltages for the row and column decoders are generated.

14. The method of claim 13, wherein the memory device comprises a switching circuit for performing the disconnecting, the transmitting and the shorting together; and wherein the switching circuit disconnects the first and second control circuits during the read operations.

15. The method of claim 13, wherein the memory device comprises a switching circuit for performing the disconnecting, the transmitting and the shorting together; and wherein the switching circuit comprises configuration switches controlled by a same signal for beginning the read operations.

16. The method of claim 13, wherein the two control circuits being disconnected are the first and second control circuits; and wherein the control circuit transmitting is the third control circuit.

17. A method of controlling a memory device comprising an array of memory cells, row and column decoders coupled to the array of memory cells, first and second charge pump voltage regulators controlled by respective first and second control circuits that supply the row and column decoders at least during write operations of data in the array of memory cells, a third charge pump voltage generator controlled by a third control circuit and supplying the row and column decoders during read operations of data from the array of memory cells, the method comprising:
executing the following steps during the read operations
disconnecting the first and second control circuits from their respective first and second charge pump voltage generators,
transmitting control signals generated by the third control circuit to said first and second charge pump voltage generators, and
shorting together output nodes of the first, second and third charge pump voltage generators on which supply voltages of the row and column decoders are generated.

18. The method of claim 17, wherein the memory device comprises a switching circuit for performing the disconnecting, the transmitting and the shorting together; and wherein the switching circuit disconnects the first and second control circuits during the read operations.

19. The method of claim 17, wherein the memory device comprises a switching circuit for performing the disconnecting, the transmitting and the shorting together; and wherein the switching circuit comprises configuration switches controlled by a same signal for beginning the read operations.
